(19) United States
(12) Patent Application Publication
(10) Pub. No.: US 2012/0241875 A1
(43) Pub. Date: Sep. 27, 2012

(54) FIELD-EFFECT TRANSISTOR AND METHOD OF MANUFACTURING THE SAME

(75) Inventor: Tsutomu Tezuka, Tsukuba-shi (JP)

(73) Assignee: Kabushiki Kaisha Toshiba

(21) Appl. No.: 13/241,444

(22) Filed: Sep. 23, 2011

(30) Foreign Application Priority Data
Mar. 25, 2011 (JP) 2011-068465

(51) Int. Cl. H01L 29/78; H01L 21/336

(52) U.S. Cl. 257/411; 438/287; 257/E29.255; 257/E21.409

(57) ABSTRACT

According to one embodiment, a field-effect transistor comprises a gate insulating film which is provided on a part of a Ge-containing substrate and the gate insulating film includes at least a GeO₂ layer, a gate electrode which is provided on the gate insulating film, a source-drain region which is provided in the substrate so as to sandwich a channel region under the gate electrode, and a nitrogen-containing region which is formed on both side parts of the gate insulating film.

### CROSS-REFERENCE TO RELATED APPLICATIONS

This application is based upon and claims the benefit of priority from prior Japanese Patent Application No. 2011-068465, filed Mar. 25, 2011, the entire contents of which are incorporated herein by reference.

### FIELD

Embodiments described herein relate generally to a field-effect transistor and a method of manufacturing the same.

### BACKGROUND

In recent years, to improve the performance of a metal-insulator-semiconductor field-effect transistor (MISFET), an attempt to use a Ge channel which is higher than a conventionally used Si channel in both electron mobility and hole mobility has been considered. With this method, higher mobility improves the current drivability of a transistor and therefore higher-speed operation or lower power consumption is expected.

However, the technique for forming a gate insulating film for a Ge channel has not been established yet. A decrease in the interface state density between Ge and a gate insulating film has become a major problem. At present, germanium dioxide (GeO₂) realizes the highest mobility as a gate insulating film interface material for the Ge-MIS transistor.

As described above, using GeO₂ as a gate insulating film interface material for the Ge-MIS transistor makes it possible to receive the full benefit of the high mobility of Ge. However, since GeO₂ is soluble in water, it might dissolve in a wet process during the manufacturing process or be deteriorated by moisture in the air. This constitutes a major cause of a decrease in the reliability of the devices and further a decrease in the process yield.

### BRIEF DESCRIPTION OF THE DRAWINGS

FIG. 1 is a sectional view showing a field-effect transistor according to a first embodiment;

FIGS. 2A, 2B, 2C, 2D, 2E, 2F, 2G and 2H are sectional views to explain the process of manufacturing a field-effect transistor according to the first embodiment;

FIGS. 3A, 3B and 3C are sectional views to explain the process of manufacturing a field-effect transistor according to a second embodiment;

FIG. 4 is a sectional view showing an element structure of a field-effect transistor according to a third embodiment;

FIGS. 5A and 5B are sectional views to explain the process of manufacturing a field-effect transistor according to the third embodiment;

FIGS. 6A, 6B, 6C and 6D are sectional views each showing an element structure of a field-effect transistor according to a modification; and

FIGS. 7A and 7B are sectional views to explain the process of manufacturing a field-effect transistor according to a modification.

### DETAILED DESCRIPTION

In general, according to one embodiment, a field-effect transistor comprises a gate insulating film which is provided on a part of a Ge-containing substrate and the gate insulating film includes at least a GeO₂ layer, a gate electrode which is provided on the gate insulating film, a source-drain region which is provided in the substrate so as to sandwich a channel region under the gate electrode, and a nitrogen-containing region which is formed on both side parts of the gate insulating film.

### First Embodiment

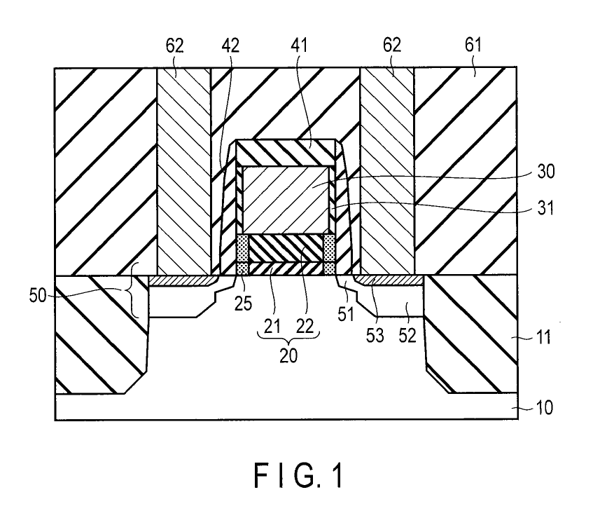

In a sectional view of an MISFET structure of FIG. 1, numeral 10 indicates a Ge substrate. On a part of the Ge substrate 10, a gate insulating film 20 is formed. The gate insulating film 20 is formed by stacking a GeO₂ layer 21 (1 nm thick) and a LaAlO₃ high-dielectric constant insulating film 22 (2.5 nm thick) sequentially. On the high-dielectric constant insulating film 22, a TaN gate electrode 30 (10 nm thick) and an SiO₂ hard mask 41 (3 nm thick) are formed sequentially. On both side surfaces of the gate electrode 30, a metal oxide film 31 is formed.

On both side surfaces of the gate stack structure composed of the gate insulating film 20, gate electrode 30, hard mask 41, metal oxide film 31, and others, a silicon nitride (SiN) gate sidewall insulating film 42 (10 nm wide at the bottom) is formed. In the substrate 10 on both sides of the gate stack structure, a source-drain region 50 is formed. The source-drain region 50 is composed of a thin extension diffusion layer 51 (10 nm thick) formed under the gate sidewall insulating film 42, a thicker diffusion layer 52 (25 nm thick) formed outside the gate sidewall film 42, and a NiGe alloy layer 53 (10 nm thick) formed on the diffusion layer 52.

On the substrate in which the gate stack structure part and source-drain region 50 have been formed, an interlayer insulating film 61 is formed. In the interlayer insulating film 61, a contact hole for contacting with the source-drain region 50 is made. In the contact hole, a metal interconnection 62 is formed so as to be embedded in the hole.

On both side surfaces of the GeO₂ layer 21, a Ge oxynitride film 25 is formed as a nitrogen-containing region. Specifically, on both side parts of the GeO₂ layer 21, the nitrogen content up to a distance of 1 nm from the side surface is 1% or more. The closest side surface region especially has a nitrogen content of 10% or more and is not soluble in water.

With this configuration, the presence of the oxynitride film 25 provided on both side surfaces of the GeO₂ layer 21 prevents the GeO₂ layer 21 from dissolving during the process and the gate from coming off. Therefore, a good process yield can be secured. In addition, the deterioration of the GeO₂ layer 21 by moisture in the air is suppressed, preventing a gate leak from increasing and the threshold value from fluctuating. Accordingly, the reliability of the MISFET is improved. Moreover, long-term deterioration of the GeO₂ layer 21 by moisture remaining in the interlayer insulating film 61 or moisture diffused from the air into the interlayer insulating film 61 is suppressed, which improves a long-term reliability.

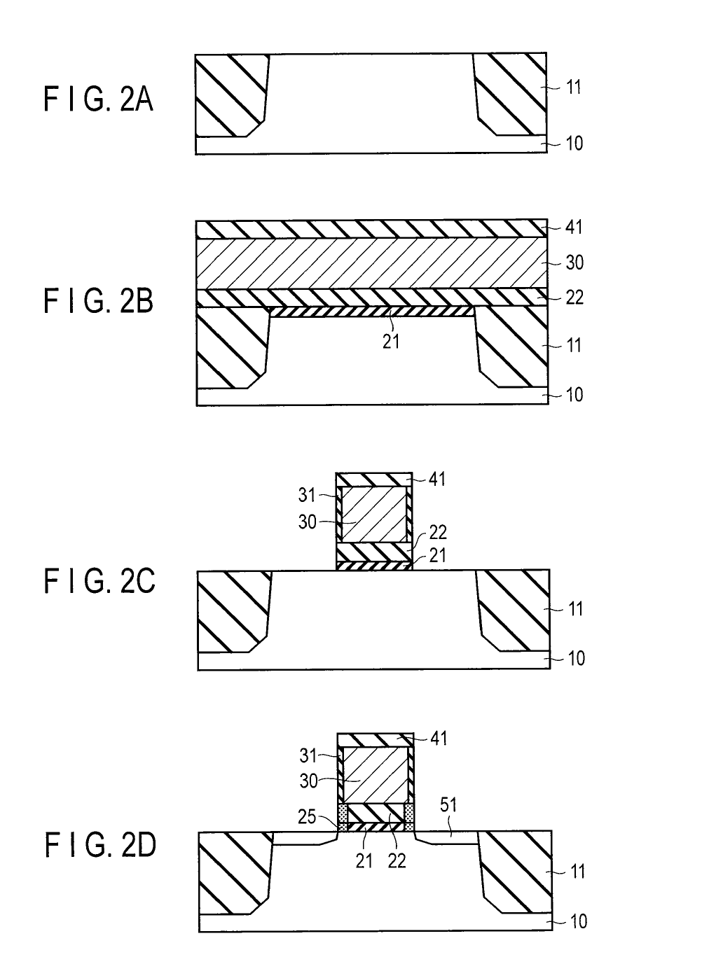

Next, the process of manufacturing a field-effect transistor of the first embodiment will be explained with reference to FIGS. 2A to 2H.

First, shallow trench isolation (STI) structures 11 are formed on the Ge substrate 10 as shown in FIG. 2A. Then, as shown in FIG. 2B, a GeO₂ layer 21 is formed to a thickness of 1 nm on the surface of the Ge substrate 10 by thermal oxidation at 550° C. Next, On the STI 11 and the GeO₂ layer 21, an LaAlO₃ high-dielectric constant insulating film 22 is deposited to a thickness of 2.5 nm, a TaN electrode film (gate electrode) 30 to a thickness of 10 nm, and an SiO₂ hard mask 41 to a thickness of 10 nm sequentially.

Next, as shown in FIG. 2C, after a gate pattern is made of a resist (not shown) by photo-lithography techniques, the hard mask 41 to GeO₂ layer 21 are selectively etched by reactive ion beam etching (RIE), thereby forming a gate stack structure part. By the above processes, a metal oxide film 31 is formed on the sidewall of the metal gate electrode 30.

Next, as shown in FIG. 2D, both side surfaces of the exposed GeO₂ layer 21 are exposed to nitrogen plasma, thereby performing a nitridation treatment. By the nitridation treatment, a Ge oxynitride film 25, a nitrogen-containing region, is formed. Although nitrogen is also contained in both side surfaces of the LaAlO₃ high-dielectric constant insulating film 22, it is not necessarily contained. A nitrogen-containing region may be formed only in both side surfaces of the GeO₂ layer 21. In addition, the nitridation treatment of the GeO₂ layer 21 is not limited to nitrogen plasma. For instance, the nitridation treatment may be performed by thermal reaction with a nitrogen radical or ammonia (NH₃).

One example of the conditions for the nitridation treatment are as follows: the substrate temperature is in the range from room temperature to 400° C. or lower at an N₂ gas pressure of 1 to 10 Pa (for plasma processing) or of 150 to 300 Pa (for a radical process) under a microwave output of 100 to 800 W. Then, after impurity ions (P, As, and Sb for nMISFETs and B and BF₂ for pMISFETs) are implanted into an extension region 51, activation annealing is performed.

Next, as shown in FIG. 2E, after a SiN film is deposited to a thickness of 10 nm on the entire surface including the gate sidewall by plasma CVD techniques or the like, the region excluding the sidewall is removed, thereby forming a gate sidewall insulating film 42. Then, after impurity ions are implanted into both sides of the gate sidewall insulating film 42, activation annealing is performed, thereby forming a source-drain diffusion layer 52. Not only the source-drain diffusion layer 52 but also the extension region 51 may be subjected to activation annealing at the same, while omitting the activation annealing process of the extension region 51.

Next, as shown in FIG. 2F, after a Ni film 55 is deposited on the entire surface, a heat treatment is performed, thereby forming a NiGe layer 53 on the source/drain. Then, the unreacted Ni is removed by acid, forming a basic structure of a MISFET as shown in FIG. 2G. Finally, as shown in FIG. 2H, after an interlayer insulating film 61 is deposited, a contact hole is made. Then, a metal interconnection 62 is embedded in the contact hole, which completes a structure shown in FIG. 1.

As described above, with the first embodiment, both side surfaces of the GeO₂ layer 21 under the gate contain nitrogen, which makes the layer 21 insoluble in water. This assures a good process yield, leading to cost reduction. In addition, deterioration by moisture in the air can be suppressed, which improves the reliability of the Ge-MIS transistor. Moreover, as the manufacturing process, the nitridation treatment shown in FIG. 2D has only to be added to an ordinary process, which makes it easier to realize the manufacturing process.

### Second Embodiment

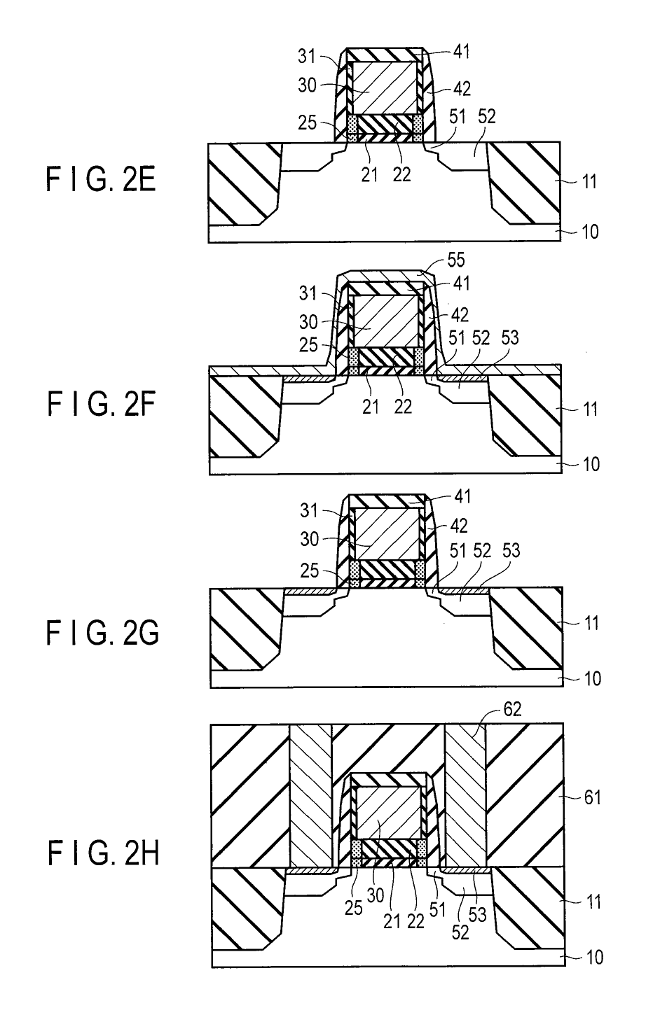

Next, the process of manufacturing a field-effect transistor according to a second embodiment will be explained with reference to FIGS. 3A to 3C. The same parts as those in FIG. 1 are indicated by the same reference numerals and a detailed explanation of them will be omitted.

The second embodiment differs from the first embodiment in the process of performing RIE to form a gate stack structure part. That is, in the RIE process, the etching of a gate electrode 30 and the etching of a gate insulating film 20 are performed in two stages instead of etching the gate electrode 30 and gate insulating film 20 at the same time.

Specifically, after the state shown in FIG. 2B, the gate electrode 30 is selectively etched by RIE using, for example, a chlorine-based gas as shown in FIG. 3A. At this time, the etching is stopped at the surface of a high-dielectric constant insulating film 22.

Next, as shown in FIG. 3B, a nitridation treatment, such as plasma nitridation, is performed and nitrogen is introduced into the GeO₂ layer 21, thereby forming a Ge oxynitride film 25. At this time, the Ge oxynitride film 25 gets into not only a part not covered with the gate electrode 30 but also a part covered with the gate electrode 30. In the nitridation treatment, nitrogen is introduced also into the high-dielectric constant insulating film 22.

Then, as shown in FIG. 3C, with a hard mask 41 and the gate electrode 30 as a mask, the high-dielectric constant insulating film 22 and Ge oxynitride film 25 are selectively etched by RIE using a fluorine compound-based gas. This etching is not necessarily limited to RIE. For example, the high-dielectric constant insulating film 22 and Ge oxynitride film 25 may be selectively etched by, for example, wet etching using dilute hydrochloric acid or the like.

From this point on, as in the first embodiment, a gate sidewall insulating film 42, a source-drain region 50, an interlayer insulating film 61, and a metal interconnection 62 are formed, which completes a field-effect transistor with the same configuration as in the first embodiment.

As described above, with the second embodiment, even if the gate electrode 30 and gate insulating film 20 are etched separately, the same configuration as that of the first embodiment is obtained. Accordingly, the second embodiment has the advantages of producing the same effect as that of the first embodiment and of reducing the overetching of the substrate 10 caused by the etching of the gate part.

### Third Embodiment

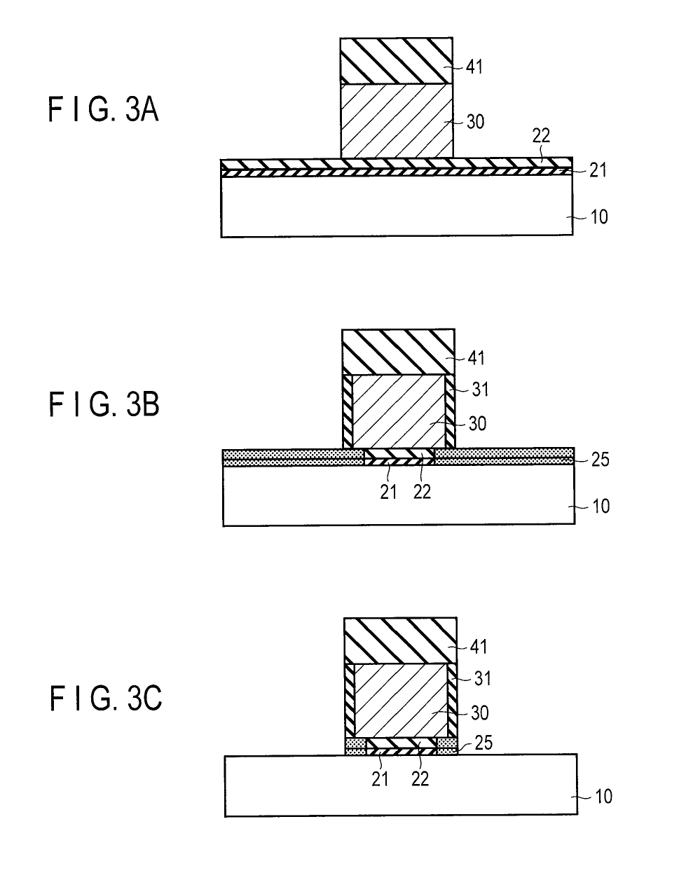

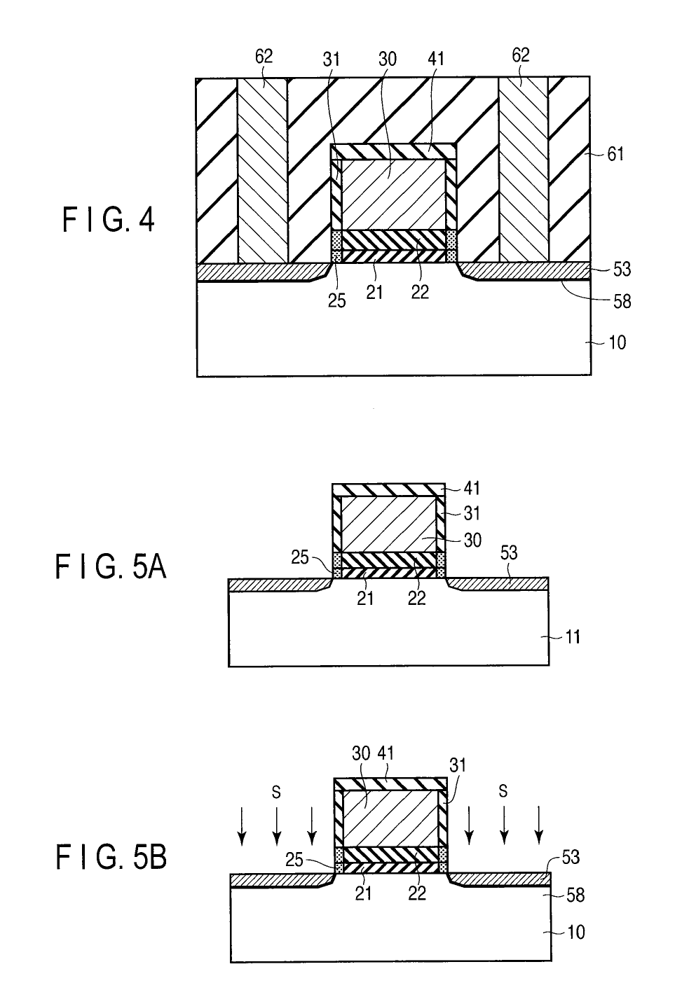

Next, the element structure of a field-effect transistor according to a third embodiment will be explained with reference to FIG. 4 and FIGS. 5A and 5B. The same parts as those in FIG. 1 are indicated by the same reference numerals and a detailed explanation of them will be omitted.

The third embodiment employs a metal source-drain structure. As shown in FIG. 4, a source-drain region 50 of the third embodiment is composed of only a NiGe layer 53 without using a diffusion layer. The NiGe layer 53 extends immediately below the gate end so as to cause carriers to be injected into an inversion layer without passing through a p-n junction. In the n-MIS transistor, a S segregation region 58 is formed near the interface between the NiGe layer 53 and Ge substrate 10.

In the case of the nMIS transistor, the segregation of S atoms near the NiGe—Ge interface is very effective to decrease the Schottky barrier against electrons. Se may be used instead of S as atoms to be segregated. In the case of a p-MIS transistor, since the Fermi level of a metal is pinned at the top of the valence band of Ge, neither S atoms nor Se atoms need be segregated. NiGe has only to be formed directly on Ge.

The manufacturing process of the third embodiment is such that the process of implanting impurity ions to form a source-drain region and the process of forming a gate sidewall are eliminated and the process of implanting S ions is added instead. The nMIS transistor requires the implantation of S ions, whereas the pMIS transistor needs no implantation of S ions.

Specifically, after a nitrogen-containing region 25 is formed by a plasma nitridation treatment in the state of FIG. 2C, an Ni film is deposited and turned into germanide by heat treatment, thereby forming a NiGe layer 53 as shown in FIG. 5A. Then, as shown in FIG. 5B, S ions are implanted, followed by heat treatment to form a S segregation region 58. After this, an interlayer insulating film 61 and a metal interconnection 62 are formed as in the first embodiment, which completes a field-effect transistor of FIG. 4.

As described above, with the third embodiment, the source-drain region 50 is composed of only the NiGe layer 53 and the remaining configuration is basically the same as that of the first embodiment. Therefore, the nitrogen-containing region 25 formed on both side surfaces of the GeO₂ layer 21 makes the GeO₂ layer 21 insoluble in water. Accordingly, the third embodiment produces the same effect as that of the first embodiment.

### Modification

This invention is not limited to the above embodiments.

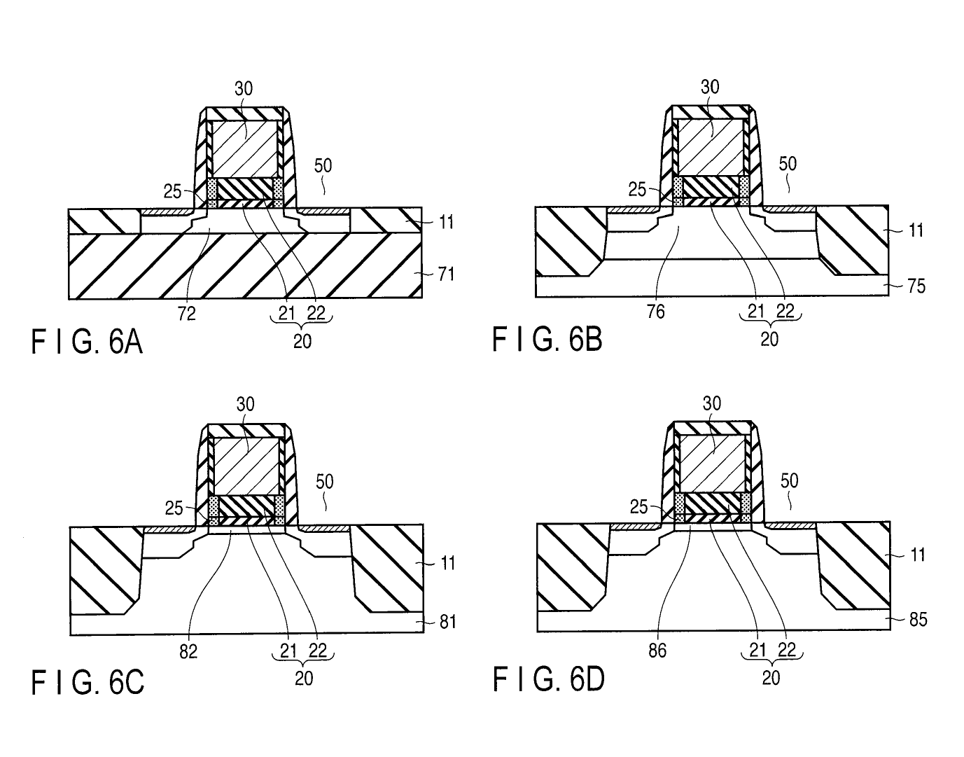

While in the embodiments, a bulk Ge substrate has been used, the invention is not restricted to this. Any suitable substrate may be used, provided that the substrate contains Ge. For instance, a germanium-on-insulator (GOI) substrate where a Ge thin film 72 has been formed on an insulating film 71 as shown in FIG. 6A or a germanium-on-silicon (GOS) substrate where a Ge layer 76 has been formed on a Si substrate 75 as shown in FIG. 6B may be used.

Instead of Ge, a strained Ge layer 82 as shown in FIG. 6C may be used as a channel. In this case, the strained Ge layer 82 is formed on an SiGe layer 81 with a Ge content of 60 to 90% and has a compressive strain resulting in an increase in the hole mobility. This configuration is particularly useful in enhancing the pMISFET performance.

In addition, the inverse configuration, that is, a strained SiGe layer 86 formed on a Ge substrate 85 may be used. In this case, the strained SiGe layer 86, which has a Ge content of 75 to 95%, has an tensile strain resulting in an increase in the electron mobility. This configuration is particularly useful in enhancing the nMISFET performance. The thickness of each of the strained layers 82, 86 is in the range of 2 to 10 nm. The Ge content and the thickness of each strained layer are set in the range that suppresses the generation of a crystal defect due to an increase in the strain and realizes a strain and a Ge content which are helpful in increasing the mobility. In addition, to apply a strain, a material differing from Ge in lattice constant may be formed in the source-drain region. For example, SiGe is embedded in the source-drain, enabling a tensile strain to be applied. Moreover, GeSn or SiGeSn is embedded in the source-drain, enabling a compressive strain to be applied.

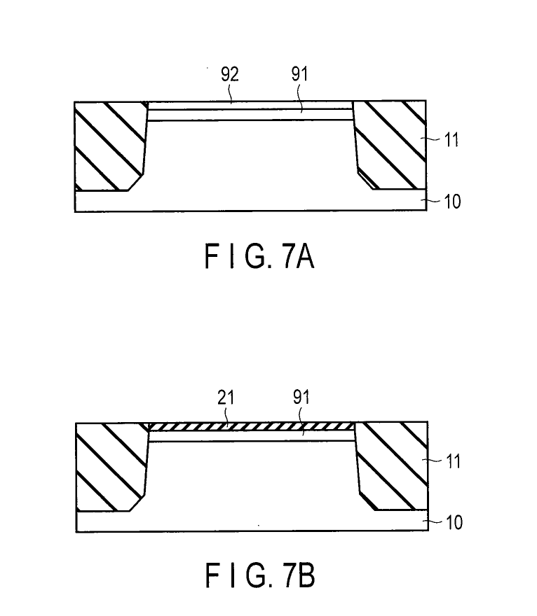

When the strained SiGe channel is used, a strained SiGe layer 91 and a Ge cap layer 92 are grown epitaxially in sequence on the Ge substrate in advance as shown in FIG. 7A. Then, the Ge cap layer 92 is thermally oxidized to form a GeO₂ layer 21 as shown in FIG. 7B.

While in the embodiments, the invention has been applied to a planar channel structure, it may be applied to a non-planar channel structure, such as a fin FET or a tri-gate structure. Furthermore, the invention may be applied to a combination of the strained Ge, strained SiGe channel, and a non-planar channel structure. The gate insulating film material is not necessarily limited to a GeO₂ layer and a LaAlO₃ layer and, of course, may be a combination of a GeO₂ layer and another high-dielectric constant insulating film (e.g., HfO₂, HfON, HfSiON, LaTiO₃, ZrO₂, LaZrO₂, Y₂O₃, Al₂O₃). In addition, the gate insulating film material is not restricted to a high-dielectric constant material. For instance, SiO₂, SiN, SiON, or the like may be used as the gate insulating film material.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A field-effect transistor comprising:
a gate insulating film which is provided on a part of a Ge-containing substrate and the gate insulating film includes at least a GeO₂ layer;
a gate electrode which is provided on the gate insulating film;
a source-drain region which is provided in the substrate so as to sandwich a channel region under the gate electrode; and
a nitrogen-containing region which is formed on both side parts of the gate insulating film.

2. The field-effect transistor of claim 1, wherein the gate insulating film has a stacked structure of the GeO₂ layer and a high-dielectric constant insulating film.

3. The field-effect transistor of claim 1, wherein the nitrogen-containing region is a Ge oxynitride film.

4. The field-effect transistor of claim 1, wherein the Ge-containing substrate is a Ge substrate.

5. The field-effect transistor of claim 1, wherein the Ge-containing substrate has a structure where a strained SiGe layer is formed on a Ge substrate.

6. The field-effect transistor of claim 1, wherein the Ge-containing substrate has a structure where a strained Ge layer is formed on a lattice-relaxed SiGe layer formed on a Si substrate.

7. The field-effect transistor of claim 1, wherein the Ge-containing substrate has a structure where a Ge layer is formed on an insulating film.

8. The field-effect transistor of claim 1, wherein the Ge-containing substrate has a structure where a Ge layer is formed on a Si substrate.

9. The field-effect transistor of claim 1, further comprising:
a gate sidewall insulating film formed on both side parts of the gate electrode.

10. The field-effect transistor of claim 9, wherein the source-drain region comprises an extension diffusion layer formed under the gate sidewall insulating film, a diffusion layer which is formed outside the gate sidewall insulating film and is thicker than the extension diffusion layer, and an alloy layer formed on the diffusion layer.

11. The field-effect transistor of claim 1, wherein the source-drain region is an alloy layer of Ge and another metal.

12. A method of manufacturing a field-effect transistor, the method comprising:
Forming, on a Ge-containing substrate, a gate insulating film which includes at least a GeO₂ layer;
forming a metal film on the gate insulating film;
etching the metal film and the gate insulating film outside a gate electrode region to form a gate stack structure part;
nitriding the surface of the gate insulating film exposed to both side surfaces of the gate stack structure part to form a nitrogen-containing region; and
forming a source-drain region on both sides of the gate stack structure part.

13. The method of claim 12, wherein the forming the gate insulating film includes forming a stacked structure of the GeO₂ layer and a high-dielectric constant insulating film.

14. The method of claim 12, wherein the nitriding the gate insulating film includes exposing the gate insulating film to plasma.

15. The method of claim 12, wherein the nitriding the gate insulating film includes exposing the gate insulating film to nitrogen radical.

16. A method of manufacturing a field-effect transistor, the method comprising:
Forming, on a Ge-containing substrate, a gate insulating film which includes at least a GeO₂ layer;
forming a metal film on the gate insulating film;
etching the metal film outside the gate electrode region to form a gate stack structure part;
nitriding the gate insulating film exposed as a result of the formation of the gate stack structure part;
selectively etching the gate insulating film with the gate electrode as a mask after nitriding the gate insulating film; and
forming a source-drain region in the substrate so as to sandwich a channel region under the gate stack structure part between the source and drain.

17. The method of claim 16, wherein the forming the gate insulating film includes forming a stacked structure of the GeO₂ layer and a high-dielectric constant insulating film.

18. The method of claim 16, wherein the nitriding the gate insulating film includes exposing the gate insulating film to plasma containing nitrogen ion.

19. The method of claim 16, wherein the nitriding the gate insulating film includes exposing the gate insulating film to nitrogen radical.
